(19) United States
(12) Patent Application Publication
(10) Pub. No.: US 2021/0305329 A1
(43) Pub. Date: Sep. 30, 2021

(54) DISPLAY PANEL, MANUFACTURING METHOD THEREOF AND DISPLAY DEVICE

(71) Applicants: Beijing BOE Display Technology Co., Ltd., Beijing (CN); BOE TECHNOLOGY GROUP CO., LTD., Beijing (CN)

(72) Inventors: Wenwen MA, Beijing (CN); Yanjun SUN, Beijing (CN); Lei LIU, Beijing (CN)

(21) Appl. No.: 17/263,983

(22) PCT Filed: May 22, 2020
(86) PCT No.: PCT/CN2020/091811

§ 371 Date: Jan. 28, 2021

(30) Foreign Application Priority Data
May 24, 2019 (CN) 201910441454.5

(51) Int. Cl. H01L 27/32; H01L 51/56

(52) U.S. Cl. CPC H01L 27/326; H01L 51/56; H01L 27/322

(57) ABSTRACT

The present disclosure provides a display panel including a plurality of pixel units. Each of the pixel units includes a substrate; a first electrode layer; a light emitting layer; a second electrode layer; and a color shift compensation layer located between the first electrode layer and the second electrode layer and on a light emitting side of the light emitting layer. The color shift compensation layer is configured to compensate for a color shift of light emitted from the light emitting layer at different viewing angles. One of the first electrode layer and the second electrode layer includes a reflective electrode layer, and the other of the first electrode layer and the second electrode layer is a transflective electrode layer. A display device including such a display panel, and a method for manufacturing such a display panel are also provided.

### CROSS-REFERENCE TO RELATED APPLICATION

The present application claims priority to Chinese Patent Application 201910441454.5 filed with the China National Intellectual Property Administration on May 24, 2019, the disclosure of which is incorporated herein by reference in its entirety.

### TECHNICAL FIELD

The present disclosure generally relates to the field of displays, and more particularly relates to a display panel, a display device including such a display panel, and a method for manufacturing such a display panel.

### BACKGROUND

Organic Light Emitting Diode (OLED) display is a technology that realizes display by means of reversible color changes of an organic semiconductor material driven by current. OLED displays have the advantages of ultra-light weight, ultra-thin thickness, higher brightness, larger viewing angle, lower voltage, lower power consumption, faster response, higher definition, shock resistance, flexibility, lower cost, simpler process, fewer raw materials, higher light emitting efficiency, wider temperature range and the like, and is considered to be a new generation of display technology with the greatest development prospect.

### SUMMARY

It is one object of the present disclosure to provide an improved display panel, a display device including such a display panel, and a method for manufacturing such a display panel.

According to an aspect of the present disclosure, there is provided a display panel including a plurality of pixel units. Each of the pixel units includes a substrate; a first electrode layer located on a side of the substrate; a light emitting layer located on a side of the first electrode layer facing away from the substrate; a second electrode layer located on a side of the light emitting layer facing away from the first electrode layer; and a color shift compensation layer located between the first electrode layer and the second electrode layer and on a light emitting side of the light emitting layer. The color shift compensation layer is configured to compensate for a color shift of light emitted from the light emitting layer at different viewing angles. In particular, one of the first electrode layer and the second electrode layer includes a reflective electrode layer, and the other of the first electrode layer and the second electrode layer is a transflective electrode layer.

As used herein, the term “reflective electrode layer” refers to an electrode layer capable of blocking transmission of light emitted from the light emitting layer, while the term “transflective electrode layer” refers to an electrode layer that is both transmittable and reflective to light emitted from the light emitting layer. Although referred to as a “transflective” electrode layer, light incident on this layer may be reflected and transmitted in any proportion, not limited to exactly 50% being reflected and 50% being transmitted.

In the above display panel, the light emitted from the light emitting layer is subjected to reflection, interference, diffraction or scattering and the like in the resonant cavity delimited by the first electrode layer and the second electrode layer, so that the emitted light is enhanced in intensity and narrowed in spectrum, and thus a color purity of the emitted light is improved, a luminous efficiency and brightness of the display panel are enhanced, and a display device of higher contrast and lower energy consumption is obtained. Meanwhile, the light emitted from the resonant cavity has better directivity, so that a subsequent black matrix manufacturing process is not needed, which saves the cost while increasing an aperture ratio of the display panel.

However, the presence of wide-angle interference in the resonant cavity may adversely affect the viewing angle characteristics of the light emitting layer, i.e., as the viewing angle moves, light emission peaks will shift, resulting in brightness differences and chromaticity shifts, especially severe color shifts at larger viewing angles. In view of this, in the above display panel, a color shift compensation layer is provided and configured to compensate for a color shift of light emitted from the light emitting layer at different viewing angles, so that light emitted by each of the pixel units at a larger viewing angle or a squint angle has the same wavelength as light emitted at a front viewing angle, thereby eliminating color shifts in the display panel and improving the display effect of the display panel.

In an exemplary embodiment, an orthographic projection of the color shift compensation layer on the substrate coincides with an orthographic projection of the light emitting layer on the substrate, so that the color shift of the light emitted from the light emitting layer at each viewing angle is sufficiently compensated, and the display effect of the display panel is improved.

In an exemplary embodiment, the color shift compensation layer includes a hemispherical transparent body, and multiple groups of filter units arranged on a hemispherical surface of the hemispherical transparent body facing away from the light emitting layer. Each of the multiple groups of filter units includes a plurality of filter units annularly arranged centering on a vertex of the hemispherical surface, wherein a first connection line between a center of each filter unit and a center of sphere of the hemispherical transparent body forms a first angle with a second connection line between the vertex and the center of sphere. In particular, all the filter units in the same group of filter units have the same first angle, and filter units in different groups of filter units have different first angles.

In an exemplary embodiment, the light emitted from the light emitting layer has a target wavelength. Each of the filter units includes a first pigment and a second pigment. The first pigment is configured such that the light passing therethrough has the target wavelength, and the second pigment is configured such that the light passing therethrough has a compensation wavelength. Masses of the first pigment and the second pigment will satisfy the following equation:

$${λ}_{t} \times ( \frac{m \text{?}}{m \text{?} + m \text{?}} ) + {λ}_{c} \times ( \frac{{m}_{2}}{m \text{?} + m \text{?}} ) = {λ}_{t} + Δ λ , \\ \text{?} \text{indicates text missing or illegible when filed}$$

where λₜ is the target wavelength, λ_{c} is the compensation wavelength, m₁ is the mass of the first pigment, m₂ is the mass of the second pigment, and Δλ is an absolute value of deviation between a light wavelength viewed from a viewing angle along the first connection line and the target wavelength in the absence of the filter units.

In an exemplary embodiment, two directly adjacent groups of filter units are arranged such that the respective Δλ thereof differ by 1 nm.

In an exemplary embodiment, each of the filter units further includes one or more of an alkali-soluble resin, a photo-curable resin, a photo-initiator, and an organic solvent.

In an exemplary embodiment, the display panel adopts an RGB color scheme, that is, the plurality of pixel units includes red pixel units, green pixel units and blue pixel units. For each of the red pixel units, the target wavelength is 610 nm, and the compensation wavelength is 630 nm. For each of the green pixel units, the target wavelength is 530 nm, and the compensation wavelength is 540 nm. For each of the blue pixel units, the target wavelength is 450 nm, and the compensation wavelength is 470 nm. Apparently, principles of the disclosure are equally applicable to display panels having other color schemes, such as RGBG, RGBW, etc.

In an exemplary embodiment, each of the filter units has a square or circular shape.

In an exemplary embodiment, each of the filter units is approximately one-thirtieth in size of one pixel unit of the display panel.

In an exemplary embodiment, the color shift compensation layer further includes a transparent substrate located between the hemispherical transparent body and the light emitting layer. The transparent substrate provides a common support for the color shift compensation layer of each pixel unit, and in the case where the color shift compensation layer includes a hemispherical transparent body, the transparent substrate may be integrally formed with the hemispherical transparent body of each pixel unit.

In an exemplary embodiment, the first electrode layer includes a reflective electrode layer, the second electrode layer is a transflective electrode layer, and the color shift compensation layer is located between the light emitting layer and the second electrode layer. A display panel having such a structure is called a top emission type display panel, in which light emitted from the light emitting layer exits from a side away from the substrate.

In an exemplary embodiment, the second electrode layer includes a reflective electrode layer, the first electrode layer is a transflective electrode layer, and the color shift compensation layer is located between the light emitting layer and the first electrode layer. A display panel having such a structure is called a bottom emission type display panel, in which light emitted from the light emitting layer exits from a substrate that is transparent.

In an exemplary embodiment, any of the above display panels is an Organic Light Emitting Diode (OLED) display panel.

In another aspect, the present disclosure provides a display device including any one of the display panels described above.

In the above display device, the light emitted from the light emitting layer is subjected to reflection, interference, diffraction or scattering and the like in the resonant cavity delimited by the first electrode layer and the second electrode layer, so that the emitted light is enhanced in intensity and narrowed in spectrum, and thus a color purity of the emitted light is improved, a display device of higher contrast and lower energy consumption is obtained. Meanwhile, the light emitted from the resonant cavity has better directivity, so that a subsequent black matrix manufacturing process is not needed, which saves the cost while increasing an aperture ratio of the display device.

Further, by providing the color shift compensation layer configured to compensate for the color shift of the light emitted from the light emitting layer at different viewing angles, light emitted by each of the pixel units at a larger viewing angle or a squint angle has the same wavelength as light emitted at a front viewing angle, thereby eliminating color shifts in the display device and improving the display effect of the display device.

In still another aspect, the present disclosure provides a method for manufacturing a display panel. The method includes: forming a first electrode layer on a side of a substrate; forming a light emitting layer on a side of the first electrode layer facing away from the substrate; forming a second electrode layer on a side of the light emitting layer facing away from the first electrode layer; and forming a color shift compensation layer between the first electrode layer and the second electrode layer and on a light emitting side of the light emitting layer, wherein the color shift compensation layer is configured to compensate for a color shift of light emitted from the light emitting layer at different viewing angles. In particular, one of the first electrode layer and the second electrode layer includes a reflective electrode layer, and the other of the first electrode layer and the second electrode layer is a transflective electrode layer.

In the display panel manufactured by the method described above, the light emitted from the light emitting layer is subjected to reflection, interference, diffraction or scattering and the like in the resonant cavity delimited by the first electrode layer and the second electrode layer, so that the emitted light is enhanced in intensity and narrowed in spectrum, and thus a color purity of the emitted light is improved, a display panel of higher contrast and lower energy consumption is obtained. Meanwhile, the light emitted from the resonant cavity has better directivity, so that a subsequent black matrix manufacturing process is not needed, which saves the cost while increasing an aperture ratio of the display panel.

Further, by forming the color shift compensation layer configured to compensate for the color shift of the light emitted from the light emitting layer at different viewing angles, light emitted by each of the pixel units at a larger viewing angle or a squint angle has the same wavelength as light emitted at a front viewing angle, thereby eliminating color shifts in the display panel and improving the display effect of the display panel.

In an exemplary embodiment, the step of forming the color shift compensation layer between the first electrode layer and the second electrode layer and on the light emitting side of the light emitting layer specifically includes: forming a plurality of hemispherical bodies on a transparent substrate by hot extrusion molding; and forming multiple groups of filter units on a hemispherical surface of the formed hemispherical body facing away from the light emitting layer by screen printing. Each group of filter units includes a plurality of filter units annularly arranged centering on a vertex of the hemispherical surface, and a first connection line between a center of each filter unit and a center of sphere of the hemispherical transparent body forms a first angle with a second connection line between the vertex and the center of sphere. In particular, all the filter units in the same group of filter units have the same first angle, and filter units in different groups of filter units have different first angles.

In an exemplary embodiment, different groups of filter units are formed using different printing screens. The printing screen is coated on the hemispherical surface in a conformal manner and has a hollowed-out portion positioned corresponding to each filter unit in the group of filter units.

In an exemplary embodiment, the light emitted from the light emitting layer has a target wavelength. The step of forming the filter units using the printing screen specifically includes applying a filter material on the printing screen. The filter material includes a first pigment configured such that the light passing therethrough has the target wavelength, and a second pigment configured such that the light passing therethrough has a compensation wavelength. In particular, masses of the first pigment and the second pigment satisfy the following equation:

$${λ}_{t} \times ( \frac{m \text{?}}{m \text{?} + {m}_{2}} ) + {λ}_{c} \times ( \frac{m \text{?}}{{m}_{1} + {m}_{2}} ) = {λ}_{t} + Δ λ , \\ \text{?} \text{indicates text missing or illegible when filed}$$

where λₜ is the target wavelength, λ_{c} is the compensation wavelength, m₁ is the mass of the first pigment, m₂ is the mass of the second pigment, and Δλ is an absolute value of deviation between a light wavelength viewed from a viewing angle along the first connection line and the target wavelength in the absence of the filter units.

In an exemplary embodiment, the transparent substrate is made of transparent plexiglass.

It should be noted that all aspects of the present disclosure have similar or identical example implementations and benefits, and are not described in detail herein.

These and other aspects of the disclosure are apparent from and will be elucidated with reference to the embodiments described hereinafter.

### BRIEF DESCRIPTION OF THE DRAWINGS

FIG. 1 schematically illustrates a viewing angle color shift in a typical display panel.

FIG. 2 schematically illustrates a cross-sectional view of a display panel according to an embodiment of the present disclosure.

FIG. 3 schematically illustrates a top view of a color shift compensation layer in a pixel unit according to an embodiment of the present disclosure.

FIG. 4 schematically illustrates a side view of a color shift compensation layer in a pixel unit according to an embodiment of the present disclosure.

FIG. 5 is a flowchart of a method for manufacturing a display panel according to an embodiment of the disclosure.

FIG. 6 schematically illustrates forming a plurality of hemispherical bodies by hot extrusion molding.

FIG. 7 schematically illustrates a top view of a printing screen for forming a group of filter units.

### DETAILED DESCRIPTION OF THE EMBODIMENTS

Exemplary embodiments of the present disclosure will be described in detail below with reference to the accompanying drawings. The drawings are schematic and not to scale, and are intended to illustrate embodiments of the disclosure only instead of limiting the scope of the disclosure. Throughout the drawings, the same reference signs denote the same or similar parts. In order to make the technical solution of the present disclosure more clear, process steps and device structures well known in the art are omitted here.

Specific examples of the display panel, the display device, and the method for manufacturing the display panel according to embodiments of the present disclosure are described below by way of example with reference to the accompanying drawings. The drawings are schematic and not to scale, and are intended to illustrate embodiments of the disclosure only instead of limiting the scope of the disclosure.

For ease of description, spatially relative terms such as “below”, “under”, “above”, “over”, and the like may be used herein to describe a relation between one element or component with another element or component as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or components would then be oriented “over” the other elements or components. Thus, the exemplary term “under” can encompass both an orientation of over and under. The device may be otherwise oriented (rotated 90 degrees, 180 degrees or at other orientations) and the spatially relative descriptors used herein are interpreted accordingly.

Hereinafter, the present disclosure is explained taking an example of an RGB color scheme including red (R) pixel units, blue (B) pixel units, and green (G) pixel units. However, as will be appreciated by those skilled in the art, the disclosure is not limited to RGB color schemes, but may be equally applicable to color schemes that include other numbers and types of pixel units.

In a typical OLED display panel, a resonant cavity is generally adopted to enhance intensity of the light emitted from the organic light emitting layer and narrow the spectrum, so that a color purity of the emitted light is improved, a luminous efficiency and brightness of the display panel are enhanced, and a display device of higher contrast and lower energy consumption is obtained. Meanwhile, the light emitted from the resonant cavity has better directivity, so that a subsequent black matrix manufacturing process is not needed, which saves the cost while increasing an aperture ratio of the display panel.

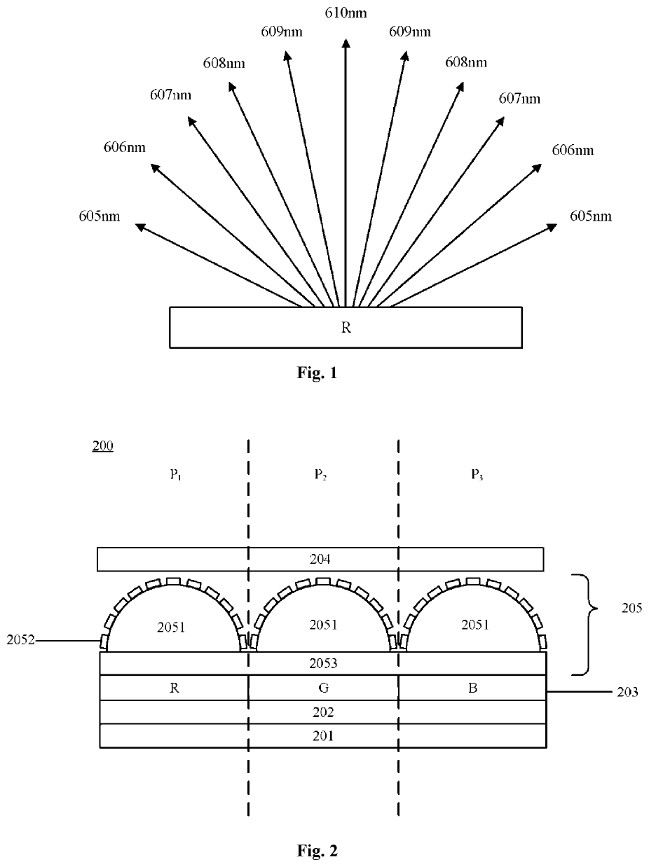

However, the resonant cavity generally includes two interference modes, i.e., wide-angle interference and multiple-beam interference, wherein the presence of the wide-angle interference may affect the viewing angle characteristics of the display panel, i.e., as the viewing angle moves, light emission peaks of the light emitting layer shifts, resulting in brightness differences and chromaticity shifts of the display panel. As shown in FIG. 1, taking a red pixel unit R as an example, an angle formed when an eye is perpendicular to a light emitting surface of the pixel unit R is referred to as a front viewing angle, at which angle the emitted light has rich color and hardly has any color shift or merely has color shifts that cannot be perceived by human eyes. Thus, the light emitted at this viewing angle has a target wavelength of substantially 610 nm. With reference to the front viewing angle, an angle formed by an eye moved to the left or right with a normal direction of the pixel unit is referred to as a squint angle, which is in a range of (0°, 90°). At a squint angle, the light emission peaks shift, so that the light emission peaks of the light emitted from the pixel unit R shift, resulting in a color shift. Typically, a resonant wavelength of the emitted light passing through the resonant cavity and the viewing angle satisfy the following relationship:

λ=2πmL*cos φ,

where λ is a resonant wavelength at different viewing angles, φ is a squint angle, L is the target wavelength of light emitted from the pixel unit, and m is the number of stages of the emission mode. As can be seen from the above equation, when the target wavelength L is constant, the squint angle φ is inversely proportional to the resonant wavelength λ. As shown in FIG. 1, as the squint angle increases, the resonant wavelength gradually decreases from the target wavelength 610 nm, so that the light emitted from the resonant cavity is severely color-shifted.

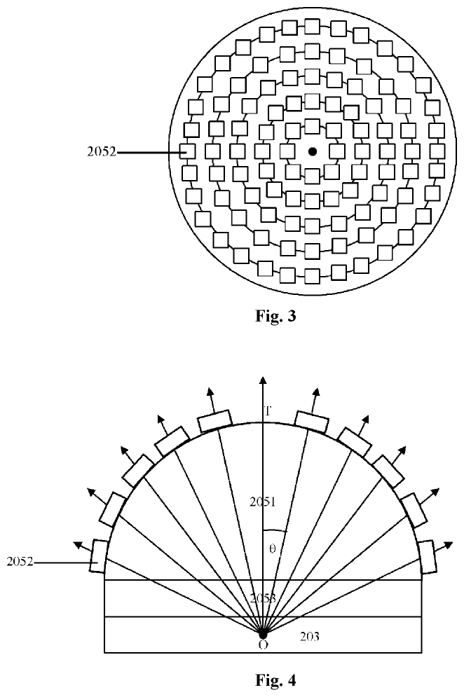

In view of this, in an embodiment of the disclosure, a display panel is provided. As shown in FIG. 2, the display panel 200 includes a plurality of pixel units P₁, P₂ and P₃. Each of the pixel units includes a substrate 201; a first electrode layer 202 located on a side of the substrate 201; a light emitting layer 203 located on a side of the first electrode layer 202 facing away from the substrate 201; and a second electrode layer 202 located on a side of the light emitting layer 203 facing away from the first electrode layer 204. Further, each of the pixel units further includes a color shift compensation layer 205 located between the first electrode layer 202 and the second electrode layer 204 and on a light emitting side of the light emitting layer 203. The color shift compensation layer 205 is configured to compensate for a color shift of light emitted from the light emitting layer 203 at different viewing angles. In particular, one of the first electrode layer 202 and the second electrode layer 204 includes a reflective electrode layer, and the other of the first electrode layer 202 and the second electrode layer 204 is a transflective electrode layer. Here, the light emitting side of the light emitting layer may be a side of the light emitting layer facing the transflective electrode layer.

In the above display panel, the light emitted from the light emitting layer is subjected to reflection, interference, diffraction or scattering and the like in the resonant cavity delimited by the first electrode layer and the second electrode layer, so that the emitted light is enhanced in intensity and narrowed in spectrum, and thus a color purity of the emitted light is improved, a luminous efficiency and brightness of the display panel are enhanced, and a display device of higher contrast and lower energy consumption is obtained. Meanwhile, the light emitted from the resonant cavity has better directivity, so that a subsequent black matrix manufacturing process is not needed, which saves the cost while increasing an aperture ratio of the display panel.

Further, in order to prevent the wide-angle interference in the resonant cavity from adversely affecting the viewing angle characteristics of the light emitting layer and eliminate the color shift at a squint angle, a color shift compensation layer is provided in the above display panel and configured to compensate for a color shift of light emitted from the light emitting layer at different viewing angles, so that light emitted by each of the pixel units at a larger viewing angle or a squint angle has the same wavelength as light emitted at a front viewing angle, thereby eliminating color shifts in the display panel and improving the display effect of the display panel.

In an embodiment of the present disclosure, the display panel may be a top emission type display panel in which, as shown in FIG. 2, light emitted from the light emitting layer 203 exits from a side away from the substrate 201. In this case, the first electrode layer 202 includes a reflective electrode layer and optionally one or more transparent electrode layers, so that the light emitted from the light emitting layer 203 cannot transmit through the first electrode layer 202. The second electrode layer 204 is a transflective electrode layer so that the light having a specific wavelength emitted from the light emitting layer 203 is emitted from the second electrode layer 204, and has an enhanced intensity and a narrowed spectrum. At this time, the color shift compensation layer 205 is located between the light emitting layer 203 and the second electrode layer 204.

Alternatively, the display panel provided in the embodiment of the present disclosure may be a bottom emission type display panel in which light emitted from the light emitting layer exits from a substrate that is transparent. In this case, the second electrode layer includes a reflective electrode layer and optionally one or more transparent electrode layers, so that the light emitted from the light emitting layer cannot transmit through the second electrode layer. Accordingly, the first electrode layer is a transflective electrode layer, and the color shift compensation layer is located between the light emitting layer and the first electrode layer.

Exemplarily, as shown in FIG. 2, an orthographic projection of the color shift compensation layer 205 in each of the pixel units P₁, P₂, P₃ on the substrate 201 coincides with an orthographic projection of the light emitting layer 203 on the substrate 201, so that the color shift of the light emitted from the light emitting layer 203 at each viewing angle is sufficiently compensated, and the display effect of the display panel is improved.

Further, in an exemplary embodiment, as shown in FIG. 2, the color shift compensation layer 205 specifically includes a hemispherical transparent body 2051, multiple groups of filter units arranged on a hemispherical surface of the hemispherical transparent body 2051 facing away from the light emitting layer 203, and optionally a transparent substrate 2053 located between the hemispherical transparent body 2051 and the light emitting layer 203. The transparent substrate 2053 provides a common support for the color shift compensation layer 205 of each pixel unit. Exemplarily, as will be further described below, the transparent substrate 2053 may be integrally formed with the hemispherical transparent body 2051 of each pixel unit.

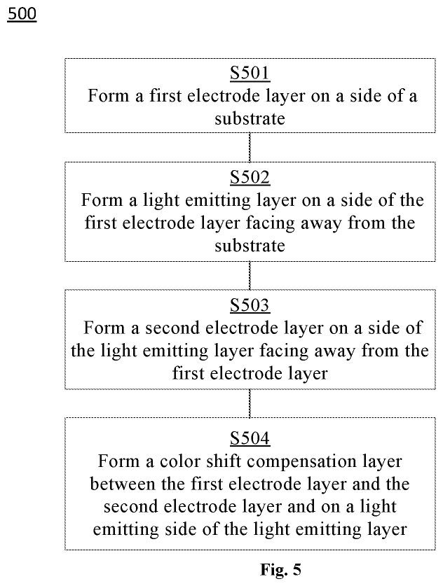

FIG. 3 schematically illustrates a top view of a color shift compensation layer 205 in a pixel unit, and FIG. 4 schematically illustrates a side view of a color shift compensation layer 205 in a pixel unit. As shown in FIGS. 3 and 4, each of the multiple groups of filter units includes a plurality of filter units 2052 annularly arranged centring on a vertex T of the hemispherical surface, that is, each group of filter units includes a plurality of filter units 2052 arranged at intervals on a ring centring on the circle center shown in FIG. 3. A first connection line O between a center of each filter unit 2052 and a center of sphere of the hemispherical transparent body 2051 forms a first angle θ with a second connection line between the vertex T and the center of sphere O. As shown in FIG. 4, all the filter units 2052 in the same group of filter units have the same first angle θ, and filter units in different groups of filter units have different first angles θ. For example, in the top view (FIG. 3) of the color shift compensation layer in the pixel unit, multiple groups of filter units are arranged on the hemispherical transparent body as concentric rings with the vertex T as a common center.

In the above embodiments, each group of filter units is configured to compensate for a color shift of light emitted from the light emitting layer at a specific viewing angle. Therefore, all the filter units in each group of filter units may have the same configuration and may be evenly spaced, while filter units of different groups of filter units differ in number and configuration.

For example, the light emitted from the light emitting layer has a target wavelength. Each of the filter units includes a first pigment and a second pigment. The first pigment is configured such that the light passing therethrough has the target wavelength, and the second pigment is configured such that the light passing therethrough has a compensation wavelength. Masses of the first pigment and the second pigment will satisfy the following equation:

$${λ}_{t} \times ( \frac{m \text{?}}{m \text{?} + {m}_{2}} ) + {λ}_{c} \times ( \frac{m \text{?}}{{m}_{1} + {m}_{2}} ) = {λ}_{t} + Δ λ , \\ \text{?} \text{indicates text missing or illegible when filed}$$

where λₜ is the target wavelength, λ_{c} is the compensation wavelength, m₁ is the mass of the first pigment, m₂ is the mass of the second pigment, and Δλ, is an absolute value of deviation between a light wavelength viewed from a viewing angle along the first connection line and the target wavelength in the absence of the filter units, Δλ, is the same for all the filter units in the same group of filter units, and varies for different groups of filter units.

In the case of an RGB color scheme, the plurality of pixel units in the display panel includes red pixel units, green pixel units and blue pixel units. For each of the red pixel units, the target wavelength is 610 nm, and the compensation wavelength is 630 nm. For each of the green pixel units, the target wavelength is 530 nm, and the compensation wavelength is 540 nm. For each of the blue pixel units, the target wavelength is 450 nm, and the compensation wavelength is 470 nm. Apparently, principles of the disclosure are equally applicable to display panels having other color schemes, such as RGBG, RGBW, etc.

In an exemplary embodiment, two directly adjacent groups of filter units are arranged such that the respective Δλ thereof differ by 1 nm. The inventors of the present disclosure have experimentally recognized that, under the existing process accuracy conditions, the scheme where groups of filter units are arranged by an interval Δλ=1 nm is the densest one and has the best compensation effect for color shifts.

It should be noted that although the filter unit 2052 is exemplarily illustrated to have a square shape in FIG. 3, the present disclosure is not limited thereto. The filter unit may have other alternative shapes, such as a circular shape, a rectangular shape, etc.

Exemplarily, each of the filter units may be approximately one-thirtieth in size of one pixel unit of the display panel, i.e., about 3 um to 7 um, and the specific size may be determined according to different product resolution designs.

Exemplarily, each of the filter units may further include one or more of an alkali-soluble resin, a photo-curable resin, a photo-initiator, and an organic solvent in addition to the first pigment and the second pigment, so as to be more easily formed on the hemispherical surface of the hemispherical transparent body.

The display panel may be an OLED display panel, and accordingly, in an embodiment of the present disclosure, there is further provide an OLED display device including the OLED display panel.

In the display device, the light emitted from the light emitting layer is subjected to reflection, interference, diffraction or scattering and the like in the resonant cavity delimited by the first electrode layer and the second electrode layer, so that the emitted light is enhanced in intensity and narrowed in spectrum, and thus a color purity of the emitted light is improved, a display device of higher contrast and lower energy consumption is obtained. Meanwhile, the light emitted from the resonant cavity has better directivity, so that a subsequent black matrix manufacturing process is not needed, which saves the cost while increasing an aperture ratio of the display device.

Further, by providing the color shift compensation layer configured to compensate for the color shift of the light emitted from the light emitting layer at different viewing angles, light emitted by each of the pixel units at a larger viewing angle or a squint angle has the same wavelength as light emitted at a front viewing angle, thereby eliminating color shifts in the display device and improving the display effect of the display device.

In another aspect, an embodiment of the disclosure provides a method 500 for manufacturing the display panel described above, as shown in FIG. 5. At step S501, a first electrode layer is formed on a side of a substrate. At step S502, a light emitting layer is formed on a side of the first electrode layer facing away from the substrate. At step S503, a second electrode layer is formed on a side of the light emitting layer facing away from the first electrode layer. At step S504, a color shift compensation layer is formed between the first electrode layer and the second electrode layer and on the light emitting side of the light emitting layer. The color shift compensation layer is configured to compensate for a color shift of light emitted from the light emitting layer at different viewing angles. One of the first electrode layer and the second electrode layer includes a reflective electrode layer, and the other of the first electrode layer and the second electrode layer is a transflective electrode layer.

The first electrode layer includes, for example, a reflective electrode layer made of such as silver, and optionally one or more transparent electrode layers made of indium tin oxide or indium zinc oxide. Accordingly, the second electrode layer is a transflective electrode layer, and may be made of, for example, a low work function metal material such as silver, aluminum, calcium, indium, lithium, magnesium, or a low work function composite metal material. Apparently, in alternative embodiments, the first electrode layer and the second electrode layer may be configured reversely, i.e., the second electrode layer includes a reflective electrode layer made of such as silver, and optionally one or more transparent electrode layers made of indium tin oxide or indium zinc oxide, while the first electrode layer is a transflective electrode layer, and may be made of, for example, a low work function metal material such as silver, aluminum, calcium, indium, lithium, magnesium, or a low work function composite metal material.

In the display panel manufactured by the method described above, the light emitted from the light emitting layer is subjected to reflection, interference, diffraction or scattering and the like in the resonant cavity delimited by the first electrode layer and the second electrode layer, so that the emitted light is enhanced in intensity and narrowed in spectrum, and thus a color purity of the emitted light is improved, a display panel of higher contrast and lower energy consumption is obtained. Meanwhile, the light emitted from the resonant cavity has better directivity, so that a subsequent black matrix manufacturing process is not needed, which saves the cost while increasing an aperture ratio of the display panel.

Further, by forming the color shift compensation layer configured to compensate for the color shift of the light emitted from the light emitting layer at different viewing angles, light emitted by each of the pixel units at a larger viewing angle or a squint angle has the same wavelength as light emitted at a front viewing angle, thereby eliminating color shifts in the display panel and improving the display effect of the display panel.

In an implementation of the step S504, the step of forming the color shift compensation layer between the first electrode layer and the second electrode layer and on the light emitting side of the light emitting layer may include: forming a plurality of hemispherical bodies on a transparent substrate by hot extrusion molding; and forming multiple groups of filter units on a hemispherical surface of the formed hemispherical body facing away from the light emitting layer by screen printing. Each group of filter units includes a plurality of filter units annularly arranged centring on a vertex of the hemispherical surface, and a first connection line between a center of each filter unit and a center of sphere of the hemispherical transparent body forms a first angle with a second connection line between the vertex and the center of sphere. All the filter units in the same group of filter units have the same first angle, and filter units in different groups of filter units have different first angles.

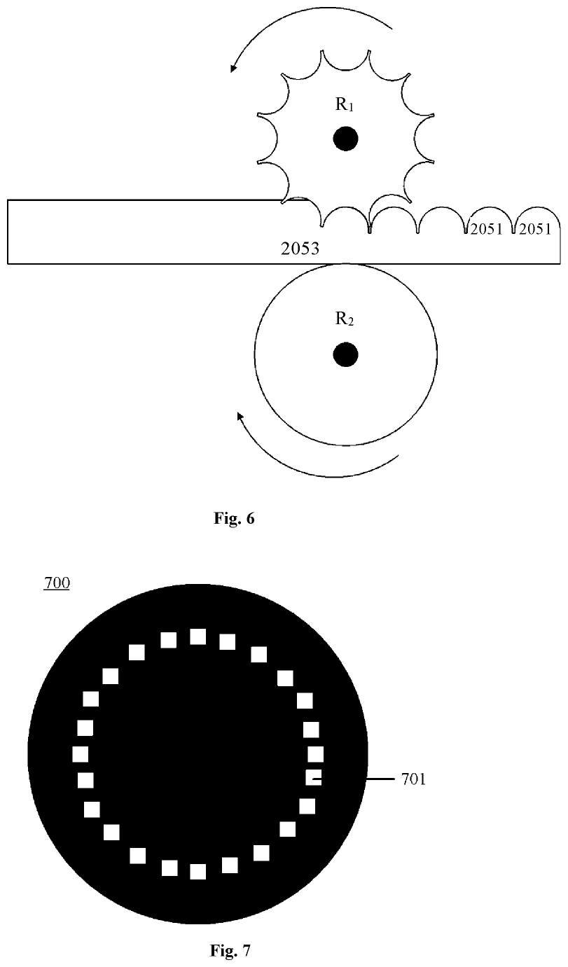

Specifically, as shown in FIG. 6, a plurality of hemispherical bodies 2051 are formed on a transparent substrate 2053 by hot extrusion molding using a hot extrusion roller R₁ and a transfer roller R₂. A rim of the hot extrusion roller R₁ has a shape complementary to the hemispherical body 2051 to be formed and rotates counterclockwise, so as to form the hemispherical body 2051 by hot extrusion molding. The transfer roller R₂ has a cylindrical shape and rotates clockwise, so as to move the transparent substrate 2053 rightward. In an exemplary embodiment, the transparent substrate may be made of transparent plexiglass.

In an exemplary embodiment, filter units of different groups of filter units are formed of different compositions, and thus, different groups of filter units are formed using different printing screens. FIG. 7 schematically illustrates a top view of a printing screen for forming a group of filter units. As shown in FIG. 7, a printing screen 700 has a hollowed-out portion 701 positioned corresponding to each filter unit in the group of filter units. In use, the printing screen is coated on the hemispherical surface in a conformal manner of the hemispherical transparent body and a filter material is applied on the printing screen such that the filter material passes through the hollowed-out portion 701 to form a plurality of filter units on the hemispherical surface.

In particular, the filter material includes a first pigment configured such that the light passing therethrough has the target wavelength of the light emitted from the light emitting layer, and a second pigment configured such that the light passing therethrough has a compensation wavelength. Masses of the first pigment and the second pigment satisfy the following equation:

$${λ}_{t} \times ( \frac{m \text{?}}{m \text{?} + {m}_{2}} ) + {λ}_{c} \times ( \frac{m \text{?}}{{m}_{1} + {m}_{2}} ) = {λ}_{t} + Δ λ , \\ \text{?} \text{indicates text missing or illegible when filed}$$

where λₜ is the target wavelength, λ_{c} is the compensation wavelength, m₁ is the mass of the first pigment, m₂ is the mass of the second pigment, and Δλ is an absolute value of deviation between a light wavelength viewed from a viewing angle along the first connection line and the target wavelength in the absence of the filter units.

Apparently, each of the filter units may further include other materials such as an alkali-soluble resin, a photo-curable resin, a photo-initiator, and an organic solvent in addition to the first pigment and the second pigment, so as to be more easily formed on the hemispherical surface of the hemispherical transparent body.

The concepts of the present disclosure may be applied broadly to any system having display functions, including desktop computers, laptops, mobile phones, tablets, and the like.

While the present disclosure has been illustrated and described in detail in the drawings and foregoing description, such illustration and description are to be considered illustrative or exemplary and not restrictive; the present disclosure is not limited to the disclosed embodiments. Other variations to the disclosed embodiments can be understood and effected by those skilled in the art in practicing the claimed disclosure, from a study of the drawings, the disclosure, and the appended claims. For example, the methods described above do not require being operated in the particular order or sequential order described to achieve desirable results. Other steps may be provided in, or steps may be eliminated from, the described methods, and other components may be added to, or components may be removed from, the described device. Other embodiments may be within the scope of the disclosure.

1. A display panel, comprising a plurality of pixel units, wherein each of the pixel units comprises:
a substrate;
a first electrode layer located on a side of the substrate;
a light emitting layer located on a side of the first electrode layer facing away from the substrate;
a second electrode layer located on a side of the light emitting layer facing away from the first electrode layer; and
a color shift compensation layer located between the first electrode layer and the second electrode layer and on a light emitting side of the light emitting layer, wherein the color shift compensation layer is configured to compensate for a color shift of light emitted from the light emitting layer at different viewing angles, and
wherein one of the first electrode layer and the second electrode layer comprises a reflective electrode layer, and the other of the first electrode layer and the second electrode layer is a transflective electrode layer.

2. The display panel according to claim 1, wherein an orthographic projection of the color shift compensation layer on the substrate coincides with an orthographic projection of the light emitting layer on the substrate.

3. The display panel according to claim 2, wherein the color shift compensation layer comprises a hemispherical transparent body, and multiple groups of filter units arranged on a hemispherical surface of the hemispherical transparent body facing away from the light emitting layer, each of the multiple groups of filter units comprises a plurality of filter units annularly arranged centering on a vertex of the hemispherical surface, a first connection line between a center of each filter unit and a center of sphere of the hemispherical transparent body forms a first angle with a second connection line between the vertex and the center of sphere, all the filter units in the same group of filter units have the same first angle, and filter units in different groups of filter units have different first angles.

4. The display panel according to claim 3, wherein the light emitted from the light emitting layer has a target wavelength, each of the filter units comprises a first pigment configured such that the light passing therethrough has the target wavelength, and a second pigment configured such that the light passing therethrough has a compensation wavelength, and masses of the first pigment and the second pigment satisfy the following equation:
$${λ}_{t} \times ( \frac{{m}_{1}}{m \text{?} + {m}_{2}} ) + {λ}_{c} \times ( \frac{m \text{?}}{{m}_{1} + {m}_{2}} ) = {λ}_{t} + Δ λ , \\ \text{?} \text{indicates text missing or illegible when filed}$$
where λₜ is the target wavelength, λ_{c} is the compensation wavelength, m₁ is the mass of the first pigment, m₂ is the mass of the second pigment, and Δλ is an absolute value of deviation between a light wavelength viewed from a viewing angle along the first connection line and the target wavelength in the absence of the filter units.

5. The display panel according to claim 4, wherein two directly adjacent groups of filter units are arranged such that the respective Δλ thereof differ by 1 nm.

6. The display panel according to claim 4, wherein each of the filter units further comprises one or more of an alkali-soluble resin, a photo-curable resin, a photo-initiator, and an organic solvent.

7. The display panel according to claim 4, wherein the plurality of pixel units comprises red pixel units, green pixel units and blue pixel units,
for each of the red pixel units, the target wavelength is 610 nm, and the compensation wavelength is 630 nm,
for each of the green pixel units, the target wavelength is 530 nm, and the compensation wavelength is 540 nm, and
for each of the blue pixel units, the target wavelength is 450 nm, and the compensation wavelength is 470 nm.

8. The display panel according to claim 3, wherein each of the filter units has a square or circular shape.

9. The display panel according to claim 3, wherein each of the filter units is approximately one-thirtieth in size of one pixel unit of the display panel.

10. The display panel according to claim 3, wherein the color shift compensation layer further comprises a transparent substrate located between the hemispherical transparent body and the light emitting layer.

11. The display panel according to claim 1, wherein the first electrode layer comprises a reflective electrode layer, the second electrode layer is a transflective electrode layer, and the color shift compensation layer is located between the light emitting layer and the second electrode layer.

12. The display panel according to claim 1, wherein the second electrode layer comprises a reflective electrode layer, the first electrode layer is a transflective electrode layer, and the color shift compensation layer is located between the light emitting layer and the first electrode layer.

13. The display panel according to claim 1, wherein the display panel is an organic light emitting diode display panel.

14. A display device, comprising the display panel according to claim 1.

15. A method for manufacturing a display panel, comprising:
forming a first electrode layer on a side of a substrate;
forming a light emitting layer on a side of the first electrode layer facing away from the substrate;
forming a second electrode layer on a side of the light emitting layer facing away from the first electrode layer; and
forming a color shift compensation layer between the first electrode layer and the second electrode layer and on a light emitting side of the light emitting layer, wherein the color shift compensation layer is configured to compensate for a color shift of light emitted from the light emitting layer at different viewing angles, and
wherein one of the first electrode layer and the second electrode layer comprises a reflective electrode layer, and the other of the first electrode layer and the second electrode layer is a transflective electrode layer.

16. The method according to claim 15, wherein the step of forming the color shift compensation layer between the first electrode layer and the second electrode layer and on the light emitting side of the light emitting layer comprises:
forming a plurality of hemispherical bodies on a transparent substrate by hot extrusion molding;
forming multiple groups of filter units on a hemispherical surface of the formed hemispherical body facing away from the light emitting layer by screen printing, wherein each group of filter units comprises a plurality of filter units annularly arranged centering on a vertex of the hemispherical surface, a first connection line between a center of each filter unit and a center of sphere of the hemispherical transparent body forms a first angle with a second connection line between the vertex and the center of sphere, all the filter units in the same group of filter units have the same first angle, and filter units in different groups of filter units have different first angles.

17. The method according to claim 16, wherein different groups of filter units are formed using different printing screens, and each of the printing screens is coated on the hemispherical surface in a conformal manner and has a hollowed-out portion positioned corresponding to each filter unit in the group of filter units.

18. The method according to claim 17, wherein
the light emitted from the light emitting layer has a target wavelength,
the step of forming the filter units using the printing screen comprises applying a filter material on the printing screen, wherein the filter material comprises a first pigment configured such that the light passing therethrough has the target wavelength, and a second pigment configured such that the light passing therethrough has a compensation wavelength, and
masses of the first pigment and the second pigment satisfy the following equation:
$${λ}_{t} \times ( \frac{{m}_{1}}{{m}_{1} + m \text{?}} ) + {λ}_{c} \times ( \frac{m \text{?}}{{m}_{1} + {m}_{2}} ) = {λ}_{t} + Δ λ , \\ \text{?} \text{indicates text missing or illegible when filed}$$
where λₜ is the target wavelength, λ_{c} is the compensation wavelength, m₁ is the mass of the first pigment, m₂ is the mass of the second pigment, and Δλ is an absolute value of deviation between a light wavelength viewed from a viewing angle along the first connection line and the target wavelength in the absence of the filter units.

19. The method according to claim 16, wherein the transparent substrate is made of transparent plexiglass.
